(19) United States
(12) Patent Application Publication
(10) Pub. No.: US 2005/0134350 A1
(43) Pub. Date: Jun. 23, 2005

(54) Analog delay circuit

(76) Inventors: Lawrence L. Huang, La Mirada, CA (US); Bhushan Asuri, Oak Park, CA (US); Anush A. Krishnaswami, San Diego, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/741,044

(22) Filed: Dec. 19, 2003

(51) Int. Cl. H03H 11/26

(52) U.S. Cl. 327/278

(57) ABSTRACT

Described is an analog delay circuit comprising a gain control circuit to determine a gain of an analog output signal with respect to an analog input signal, and a delay control circuit to determine a group delay of the analog output signal with respect to the analog input signal. The gain control circuit may determine the gain substantially independently of the group delay, and the delay control circuit may determine the group delay substantially independently of the group delay.

The subject matter disclosed herein relates to U.S. patent application Nos. [attorney docket nos. 42390.P17153, 42390.P17154, 42390.P17155 and 42390.P17559] filed concurrently with the present application.

### BACKGROUND

1. Field:

The subject matter disclosed herein relates to circuits and systems for processing analog signals.

2. Information:

To recover information from a signal received from noisy communication channel, a receiver typically employs filtering and equalization techniques to enable reliable detection of the information. Decreases in the cost of digital circuitry have enabled the cost effective use of adaptive digital filtering and equalization techniques that can optimally “tune” a filter according to the specific characteristics of a noisy communication channel.

FIG. 1 shows a conventional digital filter 10 employing a finite impulse response (FIR) configuration. An analog input signal 12 is received at an analog to digital converter (ADC) 14 to provide a digital signal at discrete sample intervals. The analog input signal 12 may be transmitting encoded symbols representing information in a noisy communication channel. The ADC 14 samples the analog input signal at discrete sample intervals corresponding with an inter-symbol temporally spacing or fractions thereof. On each discrete sample interval, the digital signal from the present discrete sample interval is provided to a multiplication circuit 20 to be scaled by coefficient co, and signal taps from the two previous discrete sample intervals (i.e., the digital signal delayed by delay circuits 16 and 26) are provided to multiplication circuits 20 to be scaled by coefficients c₂ and C₄, respectively. The outputs of the three multiplication circuits are then additively combined at a summing circuit 22 as a filtered output signal.

The delay circuits 16 and 26 store and forward digital values to provide digital output signals which are delayed versions of digital input signals. For example, the delay circuits 16 and 26 may comprise single or multi-bit latch circuits to provide digital signal taps on an interval T.

### BRIEF DESCRIPTION OF THE FIGURES

Non-limiting and non-exhaustive embodiments of the present invention will be described with reference to the following figures, wherein like reference numerals refer to like parts throughout the various figures unless otherwise specified.

FIG. 1 shows a conventional digital filter employing a finite impulse response (FIR) configuration.

FIG. 2 shows a schematic diagram of a multi-tap filter to process to an analog input signal according to an embodiment of the present invention.

FIG. 3 shows a schematic block diagram of a delay circuit to provide a delayed version of an analog input signal according to an embodiment of the multi-tap filter shown in FIG. 2.

FIGS. 4 and 5 show schematic diagrams of a gain control circuit portion of a delay circuit according to an embodiment of the delay circuit shown in FIG. 3.

FIG. 6 shows a small signal representation of a gain control circuit according to an embodiment of the gain control circuit shown in FIGS. 4 and 5.

FIG. 7 shows a schematic diagram of a delay control circuit portion of a delay circuit according to an embodiment of the delay control circuit shown in FIG. 3.

FIG. 8 shows a small signal representation of a delay control circuit according to an embodiment of the delay control circuit shown in FIG. 7.

FIG. 9 shows a schematic diagram of a receiver that may incorporate a multi-tap filter according to an embodiment of the multi-tap filter shown in FIG. 2.

### DETAILED DESCRIPTION

Reference throughout this specification to “one embodiment” or “an embodiment” means that a particular feature, structure, or characteristic described in connection with the embodiment is included in at least one embodiment of the present invention. Thus, the appearances of the phrase “in one embodiment” or “an embodiment” in various places throughout this specification are not necessarily all referring to the same embodiment. Furthermore, the particular features, structures, or characteristics may be combined in one or more embodiments.

An “analog signal” as referred to herein relates to a signal having a value that may change continuously over a time interval. For example, an analog signal may be associated with one or more voltages where each voltage may change continuously over a time interval. An analog signal may be sampled at discrete time intervals to provide a “digital signal” where one or more discrete signal values are associated with each discrete time interval and, unlike an analog signal, do not change continuously between such discrete time intervals. However, this is merely an example of an analog signal as contrasted from a digital signal and embodiments of the present invention are not limited in these respects.

A signal may be “tapped” to provide signal taps or delayed versions of a signal to be processed. A “multi-tap filter” as referred to herein relates to circuitry or logic to process a signal by individually processing the signal at distinct signal taps and combining the individually processed signal taps to provide an equalized signal. For example, a multi-tap filter may comprise one or more delay elements to generate one or more signal taps. An amplitude of each of the signal taps may then be scaled by a corresponding “coefficient.” The scaled versions of the signal taps may then be combined to provide an equalized output signal. However, this is merely an example of a multi-tap filter and embodiments of the present invention are not limited in these respects.

A signal tap or delayed version of an input analog signal may be characterized as having a “group delay” identifying a time shift between the input analog signal and the delayed version.

Briefly, an embodiment of the present invention relates to an analog delay circuit to impart a group delay to an analog input signal. The analog delay circuit may comprise a gain control circuit to determine a gain of the analog output signal with respect to the analog input signal and a delay control circuit to determine a group delay of the analog output signal with respect to the analog input signal. The gain control circuit may determine the gain substantially independently of the group delay, and the delay control circuit may determine the group delay substantially independently of the group delay. However, this is merely an example embodiment and other embodiments are not limited in these respects.

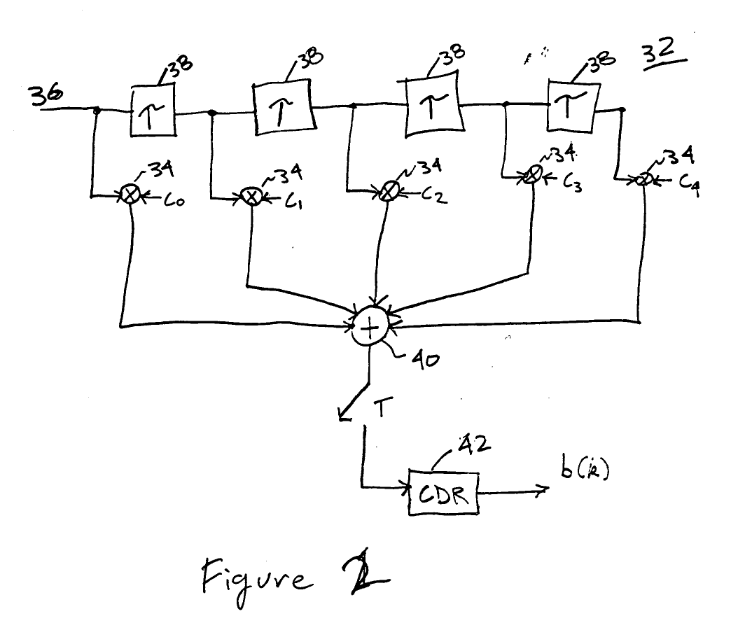

FIG. 2 shows a schematic diagram of a multi-tap filter 32 to process an analog input signal 36 according to an embodiment of the present invention. In one embodiment, the analog input signal 36 may comprise information encoded in symbols at symbol intervals in the analog input signal 36. Delayed versions or analog signal taps of the analog input signal 36 may be scaled by a corresponding coefficient (e.g., a corresponding one of c₀ through C₄) at a corresponding multiplication circuit 34, and a summing circuit 40 may additively combine the outputs of the multiplication circuits 34 to generate an equalized analog output signal. The equalized analog output signal may then be sampled at symbol intervals T to enable detection of encoded symbols b(k) at clock and data recover circuit 42.

According to an embodiment, analog signal taps or delayed versions of the analog input signal 36 may be generated by delay circuits 38 at a group delay of τ. The delay circuits 38 may be designed to have a group delay τ between an analog input signal and an analog signal tap of, for example, a symbol interval or fractions thereof. However, these are merely examples of a group delay that may be imparted to an analog input signal in the form of an analog signal tap and embodiments of the present invention are not limited in these respects.

FIG. 3 shows a schematic block diagram of a delay circuit 50 to provide a delayed version of an analog input signal according to an embodiment of the multi-tap filter 32 shown in FIG. 2. It should be understood, however, that the multi-tap filter 32 merely provides an example of how the delay circuit 50 may be implemented for a specific application and that the delay circuit 50 may be implemented in other applications without departing from the invention. The delay circuit 50 comprises five stages 52 through 60 and generates a differential output signal from a final stage 60 in response to a differential input signal received at a first stage 52. A first stage 52 may comprise a gain control circuit to impart a gain to the output signal with respect to the input signal based upon a magnitude of a current signal from a current source 62. A third stage 56 and final stage 60 may each comprise a delay control circuit to impart a group delay to the output signal based upon a magnitude of a current signal from a current source 64. Accordingly, the first stage 52 may control the gain of the output signal substantially independently of the group delay (imparted by the stages 56 and 60) and the stages 56 and 60 may control the group delay associated with the output signal substantially independently of the gain of the output signal (imparted by the stage 52).

In the illustrated embodiment, the stages 52, 56 and 60 may be formed to include emitter follower circuit topologies while the stages 54 and 58 may be formed to include common emitter topologies with emitter resistive degeneration. Additionally, the stage 54 may incorporate a capacitance coupled to the stage 52 through a buffer circuit to impart at least a portion of the overall group delay as described in U.S. patent application No. [attorney docket no. 42390.P17559], incorporated herein by reference.

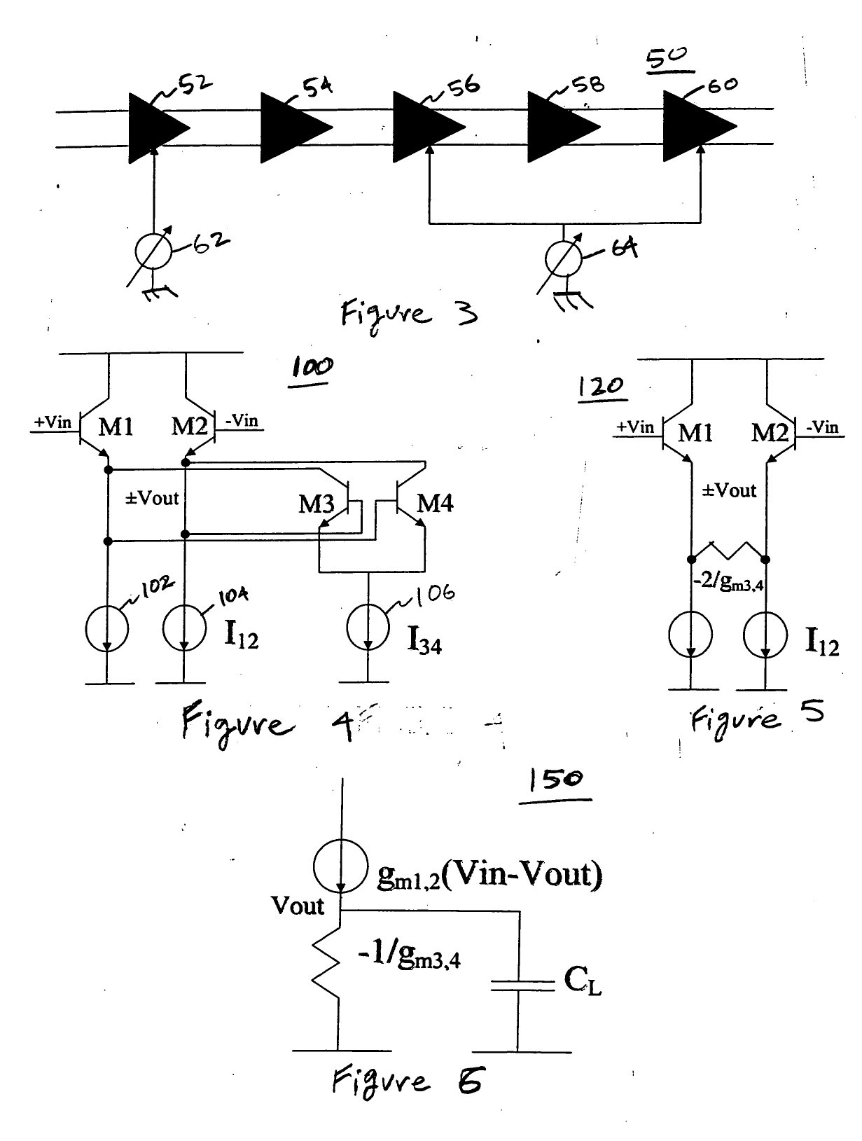

FIGS. 4 and 5 show schematic diagram representations of a gain control circuit portion 100 of a delay circuit according to an embodiment of the stage 52 shown in FIG. 3. A differential analog input signal is received on base terminals of transistors M1 and M2 to provide an output signal (e.g., to stage 54) on emitter terminals coupled to current sources 102 and 104. Transistors M3 and M4 (each being associated with a gain of gₘ) are coupled to the emitter terminals to impart a negative resistance −2/gₘ as illustrated in representation 120 of FIG. 5. Current sources 102 and 104 coupled to transistors M1 and M2, respectively, may each maintain a current of I₁₂ while a current source 106 coupled to transistors M3 and M4 may maintain a current of I₃₄. As illustrated below, the magnitude of the current I₁₂ may be set relative to the magnitude of current I₃₄ to affect the resulting gain of the gain control circuit portion 100.

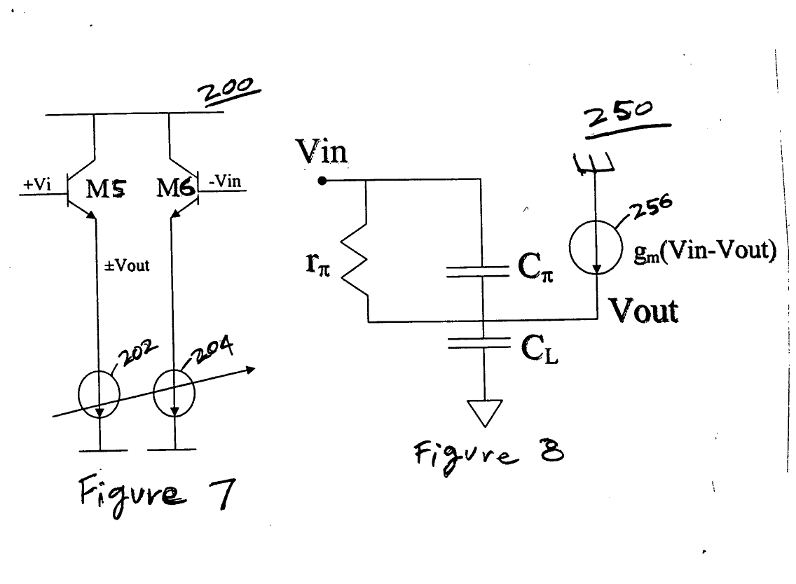

FIG. 6 shows a small signal representation of a gain control circuit according to an embodiment of the gain control circuit 100 shown in FIG. 4. In the illustrated embodiment, the gain of the gain control circuit portion 100 as provided may be modeled in equation (1) as the following gain transfer function:

$$\frac{{V}_{out}}{{V}_{in}} = \frac{- {g}_{m1 , 2}}{{g}_{m3 , 4} - {g}_{m1 , 2} - {sC}_{L}} \qquad ( 1 )$$

where:
g_{m1,2}=transconductance associated with transistor pair M1 and M2;
g_{m3,4}=transconductance associated with transistor pair M3 and M4; and
C_{L}=parasitic capacitance between output terminals.

The quantity −2/g_{m3,4} may model a negative resistance applied to the output terminals of gain control circuit portion 100 (indicated as −1/g_{m3,4} in the half circuit, small signal representation of FIG. 6). According to an embodiment, g_{m3,4} is a function of the current I₃₄. I₃₄ may therefore be set to provide an appropriate negative resistance at the output terminals. As illustrated with the gain transfer function in equation (1) above, an increase in g_{m3,4} (e.g., from setting current I₃₄ and while maintaining I₁₂ and g_{m1,2} constant) may result in a decreased gain while a decrease in g_{m3,4} may result in an increased gain.

FIG. 7 shows a schematic diagram of a delay control circuit portion of a delay circuit according to an embodiment of either of the delay control circuits 56 or 60 shown in FIG. 3. Transistors M5 and M6 in an emitter follower topology may receive a differential input signal at base terminals and provide a differential output signal at emitter terminals. Current sources 202 and 204 may be set (e.g., to maintain matching current magnitudes) to provide a particular gain gₘ associated with the transistors M5 and M6.

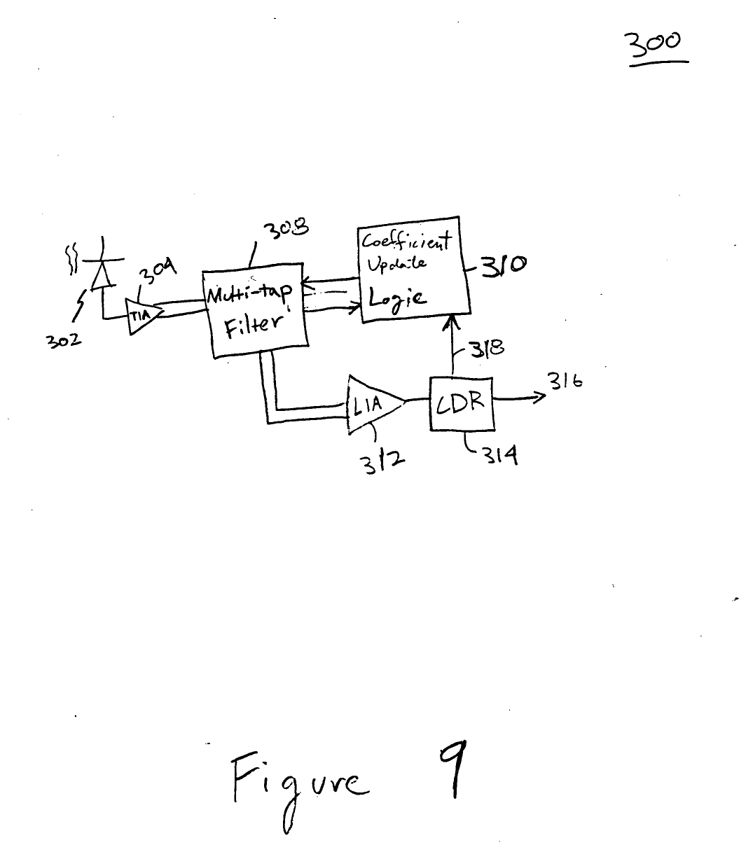

FIG. 8 shows a small signal representation 250 of the delay control circuit 200 shown in FIG. 7. A current source 256 may generate a current magnitude based upon a gain associated with the transistor pair M5 and M6, gₘ, and the voltage difference between the input and output signals. Capacitor C_{π} represents an internal capacitance between base and emitter terminals of either the transistor M5 or M6, a capacitor C_{L} represents a parasitic capacitance associated with other portions of the delay control circuit 200 and resistor r_{π} represents an inherent resistance of either transistor M5 or M6 between base and emitter terminals. The capacitance C_{π} may vary in response to variations in the magnitude of current sources 202 and 204. For example, the capacitance C_{π} may vary substantially in proportion to changes in the magnitude of the current sources 202 and 204.

The gain transfer function of the small signal representation may be expressed in equation (2) as follows:

$$\frac{{V}_{out}}{{V}_{in}} = \frac{1 + \frac{{sr}_{π} {C}_{π}}{1 + {g}_{m} {r}_{π}}}{1 + \frac{s ( {r}_{π} {C}_{π} + {r}_{π} {C}_{L} )}{1 + {g}_{m} {r}_{π}}} \qquad ( 2 )$$

According to an embodiment, a group delay (GD) imparted by the delay control circuit 200 may be expressed in equation (3) as a function of a pole frequency in the gain transfer function as follows:

$$GD ∝ - \frac{ⅆ ϕ}{ⅆ f} = \frac{( {ω}_{p} )}{{ω}_{p}^{2} + {ω}^{2}} \\ where \text{:} \\ \frac{ⅆ ϕ}{ⅆ f} = first derivative of the phase of the gain transfer function with respect to frequency ; \qquad ( 3 )$$

ω=an operating bandwidth of the delay control circuit 200; and
ωₚ=a pole frequency of the gain transfer function.

From the above the gain transfer function expressed above, the pole frequency may be expressed in equation (4) as follows:

$${ω}_{p} = \frac{1 + {g}_{m} {r}_{π}}{{r}_{π} {C}_{π} + {r}_{π} {C}_{L}} \approx \frac{{g}_{m}}{{C}_{π} + {C}_{L}} if {g}_{m} {r}_{π} >> 1 \qquad ( 4 )$$

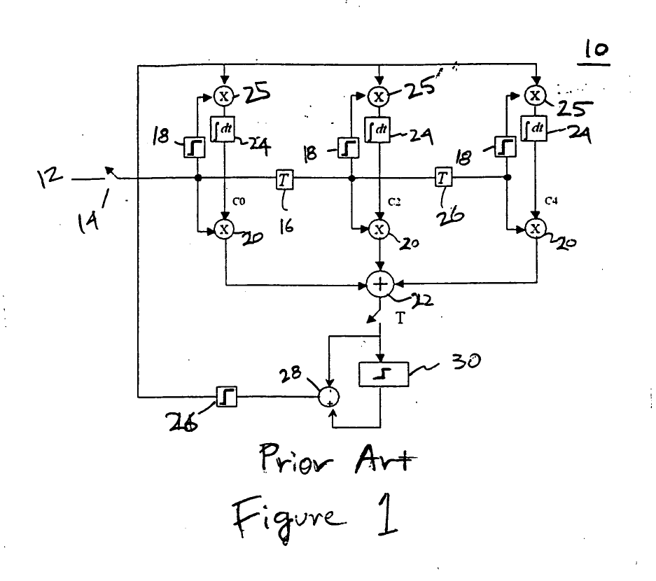

From equation (4), ωₚ is a decreasing function of C_{π} (from changes in the magnitude of current sources 202 and 204). GD is an asymptotically decreasing function of C_{π} (from equations (3) and (4)). C_{π} may be substantially directly proportional changes in the magnitude of current sources 202 and 204. Accordingly, as the magnitude of current sources 202 and 204 increases, C_{π} and ωₚ increase, thereby decreasing GD. As discussed above, the gain of the analog delay circuit 50 may be controlled at the gain control circuit 52 by controlling the magnitude of current source 62 (FIG. 1). Independently of the gain set by the gain control circuit 52, a group delay of the analog delay circuit 50 may be controlled at the delay control circuits 56 and 60 by controlling a magnitude of the current source 64.

According to an embodiment, the multi-tap filter 32 may be implemented as part of a receiver 300 as shown in FIG. 9. A transimpedance amplifier 304 may receive a current signal from a photodiode 302 in response to exposure to light energy (e.g., from a fiber optic cable). The transimpedance amplifier 304 may convert the current signal into an analog input signal expressed as a voltage signal representing the intensity of light energy received at the photodiode 302. A multi-tap filter 308 may process the analog input signal using a multi-tap filter as illustrated above with reference to FIGS. 2 and 3 to provide an equalized analog output signal to a limiting amplifier (LIA) 312. The LIA 312 may then map the equalized analog output signal to specific voltages in a range of voltages. A clock and data recovery (CDR) circuit 314 may associate the mapped voltages with symbols on symbol intervals which are provided at output 316, and generate inter-symbol timing information 318.

According to an embodiment, coefficient update logic 310 may provide periodically updated coefficients to the multi-tap filter 308 based upon estimated errors in the detection of symbols from the equalized analog output signal and the inter-symbol timing information 318. The multi-tap filter 308 provides an equalized analog output signal from an analog input signal without digitally sampling the analog input signal. Accordingly, no analog to digital conversion of the analog input signal is needed prior to filtering at the multi-tap filter. A functional controller (FC) 306 may initialize coefficients in the multi-tap filter 308 and the coefficient update logic 310 at startup.

While the receiver 300 is shown receiving an analog input signal from a photodiode and transimpedance amplifier, it should be understood that the architecture of receiver 300 may be adapted for processing an analog input signal from different transmission media. For example, other embodiments may be adapted for processing an analog input signal received as a differential signaling pair signal over unshielded twisted wire pair cabling or over a device to device interconnection formed in a printed circuit board.

The receiver 300 may be included as part of an optical transceiver (not shown) to transmit or receive optical signals in an optical transmission medium such as fiber optic cabling. The optical transceiver may modulate a transmitted signal or demodulate a received signal 312 according to any optical data transmission format such as, for example, wave division multiplexing wavelength division multiplexing (WDM) or multi-amplitude signaling (MAS). For example, a transmitter portion of the optical transceiver may employ WDM for transmitting multiple “lanes” of data in the optical transmission medium.

The multi-tap filter 308 and LIA 312 may form a physical medium dependent (PMD) section of the receiver 300. Such a PMD section may also provide power from a laser driver circuit (not shown) to a laser device (not shown). The CDR circuit 114 may be included in a physical medium attachment section coupled to the PMD section. Such a PMA section may also include de-multiplexing circuitry (not shown) to recover data from a conditioned signal received from the PMD section, multiplexing circuitry (not shown) for transmitting data to the PMD section in data lanes, and a serializer/deserializer (Serdes) for serializing a parallel data signal from a layer 2 section (not shown) and providing a parallel data signal to the layer 2 section based upon a serial data signal provided by the CDR circuit 314.

According to an embodiment, the layer 2 section may comprise a media access control (MAC) device coupled to the PMA section at a media independent interface (MII) as defined IEEE Std.802.3ae-2002, clause 46. In other embodiments, the layer 2 section may comprise forward error correction logic and a framer to transmit and receive data according to a version of the Synchronous Optical Network/Synchronous Digital Hierarchy (SONET/SDH) standard published by the International Telecommunications Union (ITU). However, these are merely examples of layer 2 devices that may provide a parallel data signal for transmission on an optical transmission medium, and embodiments of the present invention are not limited in these respects.

The layer 2 section may also be coupled to any of several input/output (I/O) systems (not shown) for communication with other devices on a processing platform. Such an I/O system may include, for example, a multiplexed data bus coupled to a processing system or a multi-port switch fabric. The layer 2 section may also be coupled to a multi-port switch fabric through a packet classification device. However, these are merely examples of an I/O system which may be coupled to a layer 2 device and embodiments of the present invention are not limited in these respects.

While there has been illustrated and described what are presently considered to be example embodiments of the present invention, it will be understood by those skilled in the art that various other modifications may be made, and equivalents may be substituted, without departing from the true scope of the invention. Additionally, many modifications may be made to adapt a particular situation to the teachings of the present invention without departing from the central inventive concept described herein. Therefore, it is intended that the present invention not be limited to the particular embodiments disclosed, but that the invention include all embodiments falling within the scope of the appended claims.

1. An analog delay circuit to generate an analog output signal in response to an analog input signal, the analog delay circuit comprising:
a gain control circuit to determine a gain of the analog output signal with respect to the analog input signal; and
a delay control circuit to determine a group delay of the analog output signal with respect to the analog input signal,
wherein the gain control circuit determines the gain substantially independently of the group delay, and the delay control circuit determines the group delay substantially independently of the group delay.

2. The analog delay circuit of claim 1, wherein the gain control circuit comprises:
first and second output terminals; and
a negative resistance circuit coupled across the first and second output terminals.

3. The analog delay circuit of claim 2, wherein the gain control circuit further comprises an emitter follower stage to provide an output signal to the first and second output terminals in response to a signal on first and second input terminals.

4. The analog delay circuit of claim 2, wherein the gain control circuit further comprises a first current source coupled to at least one of the first and second output terminals to generate a first current having a first magnitude and a second current source coupled to the negative resistance circuit to generate a second current having a second magnitude, wherein the gain comprises a second current source, and wherein the gain of the analog delay circuit is based, at least in part, on the second magnitude relative to the first magnitude.

5. The analog delay circuit of claim 1, wherein the delay control circuit comprises:
first and second output terminals; and
a current source having a magnitude, the current source being coupled to at least one of the first and second output terminals,
wherein the group delay is based, at least in part, on a magnitude of the current source.

6. The analog delay circuit of claim 5, wherein the delay control circuit comprises first and second transistors to provide an emitter-follower stage coupled, and wherein the first and second transistors comprise a capacitance that varies in response to changes in the magnitude of the current source.

7. A method comprising:
receiving an analog input signal;
generating an analog output signal having a group delay with respect to the analog input signal;
imparting a gain to the analog output signal with respect to the analog input signal substantially independently of the group delay; and
maintaining the group delay substantially independently of the gain.

8. The method of claim 7, wherein imparting the gain to the analog output signal further comprises applying a negative resistance circuit across first and second output terminals.

9. The method of claim 8, wherein the method further provide an output signal to the first and second output terminals in response to a signal on first and second input terminals of an emitter follower stage.

10. The method of claim 8, wherein the method further comprises:
generating a first current having a first current magnitude from a first current source coupled to the negative resistance; and
generating a second current having a second current magnitude from a second current source coupled to the negative resistance,
wherein the gain of the analog delay circuit is based, at least in part, on the second magnitude relative to the first magnitude.

11. The method of claim 7, wherein the method further comprises transmitting the analog output signal on first and second output terminals, and wherein maintaining the group delay further comprises maintaining a magnitude of a current source coupled to at least one of the first and second output terminals.

12. The method of claim 11, wherein the first output terminal is coupled to a first transistor and the second output terminal is coupled to a second transistor, and wherein the method further comprises varying a capacitance between the first and second transistors in response to changes in the magnitude of the current source.

13. A system comprising:
a receiver adapted to process the analog input signal from a transmission medium, the receiver comprising:
a plurality of analog delay circuits to generate a plurality of analog signal taps in response to analog input signal;
a multi-tap filter to apply each of a plurality of coefficients to a corresponding one of the analog signal taps to provide an equalized analog signal; and
a clock and data recovery circuit to recover temporally spaced symbols from the equalized analog signal as a serial data signal; and
a deserializer to provide a parallel data signal in response to the serial data signal, wherein, each analog delay circuit further comprises:
a gain control circuit to determine a gain of an associated analog signal tap; and
a delay control circuit to determine a group delay of the associated analog signal tap with respect to the analog input signal, wherein the gain control circuit determines the gain substantially independently of the group delay, and the delay control circuit determines the group delay substantially independently of the group delay.

14. The system of claim 13, wherein the system further comprises:
a photodiode capable of being to an optical transmission medium; and
a transimpedance amplifier to generate the analog input signal in response to a current from the photodiode.

15. The system of claim 13, the system further comprising a SONET framer to receive the parallel data signal.

16. The system of claim 15, wherein the system further comprises a switch fabric coupled to the SONET framer.

17. The system of claim 13, the system further comprising an Ethernet MAC to receive the parallel data signal.

18. The system of claim 17, wherein the system further comprises a multiplexed data bus coupled to the Ethernet MAC.

19. The system of claim 14, wherein the system further comprises a switch fabric coupled to the Ethernet MAC.

20. The system of claim 17, wherein the system further comprises a XAUI link coupled between the deserializer and the Ethernet MAC.

21. The system of claim 13, wherein the gain control circuit comprises:
first and second output terminals; and
a negative resistance circuit coupled across the first and second output terminals.

22. The system of claim 21, wherein the gain control circuit further comprises an emitter follower stage to provide an output signal to the first and second output terminals in response to a signal on first and second input terminals.

23. The system of claim 21, wherein the gain control circuit further comprises a first current source coupled to at least one of the first and second output terminals to generate a first current having a first magnitude and a second current source coupled to the negative resistance circuit to generate a second current having a second magnitude, wherein the gain comprises a second current source, and wherein the gain of the analog delay circuit is based, at least in part, on the second magnitude relative to the first magnitude.

24. The system of claim 13, wherein the delay control circuit comprises:
first and second output terminals; and
a current source having a magnitude, the current source being coupled to at least one of the first and second output terminals,
wherein the group delay is based, at least in part, on a magnitude of the current source.

25. The system of claim 24, wherein the delay control circuit comprises first and second transistors to provide an emitter-follower stage, and wherein the first and second transistors comprise a capacitance that varies in response to changes in the magnitude of the current source.
